(19) United States
(12) Patent Application Publication
(10) Pub. No.: US 2025/0294908 A1
(43) Pub. Date: Sep. 18, 2025

(54) SEMICONDUCTOR STRUCTURE INCLUDING EVENT SENSOR AND METHOD FOR MANUFACTURING THE SAME

(71) Applicant: TAIWAN SEMICONDUCTOR MANUFACTURING COMPANY LTD., HSINCHU (TW)

(72) Inventors: CHUN-LIANG LU, TAINAN CITY (TW); CHIA-YU WEI, TAINAN CITY (TW); CHUN-HAO CHOU, TAINAN CITY (TW); KUO-CHENG LEE, TAINAN CITY (TW)

(21) Appl. No.: 18/603,259

(22) Filed: Mar. 13, 2024

(51) Int. Cl. H01L 27/146; H01L 23/00

(52) U.S. Cl. CPC H10F 39/809; H10F 39/018; H10F 39/811; H01L 24/08; H01L 2224/08145; H10F 39/199

(57) ABSTRACT

A semiconductor structure includes an image sensor, disposed in a first substrate, wherein the first substrate includes a front side and a backside, and the image sensor is configured to receive an optical signal from the backside of the first substrate; an event sensor, disposed in the first substrate adjacent to the image sensor; a capacitor structure, disposed in a second substrate, wherein the second substrate is disposed at the front side of the first substrate, and wherein a first electrode of the capacitor structure is electrically connected to the event sensor; and a logic device, disposed in a third substrate, wherein the third substrate is disposed at the front side of the first substrate, wherein a second electrode of the capacitor structure is electrically connected to the logic device. A method of manufacturing the semiconductor structure is also provided.

### BACKGROUND

Digital cameras and other imaging devices employ image sensors. Image sensors convert optical images to digital data that may be represented as digital images. One type of image sensor commonly used in optical imaging devices is a backside illumination (BSI) sensor. BSI sensor fabrication can be integrated into conventional semiconductor processes for low cost, small size, and high integration. Further, BSI sensors have advantages such as low operating voltage, low power consumption, high quantum efficiency, low read-out noise, and ability to allow random access. BSI sensors are commonly used in cameras of mobile devices, such as smart phones. When an event-based vision sensor (EVS) is applied in a BSI sensor for better dynamic vision, a high capacitance for processing electrons from the EVS is required. However, as the semiconductor industry has progressed into advanced technology process nodes in pursuit of smaller product scales, an obstacle of providing sufficient space for capacitors in a small-scale package has been encountered.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIGS. 1, 2 and 3 are schematic cross-sectional diagrams of semiconductor structures in accordance with different embodiments of the present disclosure.

FIGS. 4A, 4B and 4C are schematic diagrams in accordance with different embodiments of the present disclosure showing application of an event sensor in BSI sensors with different colors.

FIG. 5A is a schematic diagram in accordance with some embodiments of the present disclosure showing the event sensor applied in a BSI sensor without a color filter.

FIG. 5B is a schematic diagram in accordance with some embodiments of the present disclosure showing BSI sensors on a wafer including multiple event sensors.

FIG. 6 is a schematic diagram showing different event sensors with different colors designed to connect to capacitors having different capacitances in accordance with some embodiments of the present disclosure.

FIG. 7 is a schematic diagram showing an event sensor applied in a pixel, wherein the pixel can electrically connect to one or more trench capacitors in series, in accordance with some embodiments of the present disclosure.

FIGS. 8, 9, 10, 11, 12, 13, 14 and 15 are schematic cross-sectional diagrams at different stages of formation of a trench capacitor in accordance with some embodiments of the present disclosure.

FIGS. 16 to 17 are schematic diagrams at different stages of formation of the semiconductor structure shown in FIG. 1 in accordance with some embodiments of the present disclosure.

FIGS. 18 to 19 are schematic diagrams at different stages of formation of the semiconductor structure shown in FIG. 3 in accordance with some embodiments of the present disclosure.

FIGS. 20A, 20B, 20C, 20D and 20E are schematic diagrams of top views of trench capacitors in accordance with different embodiments of the present disclosure.

FIGS. 21A, 21B, 21C, 21D and 21E are schematic diagrams of top views of trench capacitors in accordance with different embodiments of the present disclosure, showing trench capacitors having similar or identical configurations in a same wafer.

FIGS. 22A, 22B and 22C are schematic diagrams of top views of trench capacitors in accordance with different embodiments of the present disclosure, showing trench capacitors having different configurations in a same wafer.

FIG. 23 is a schematic cross-sectional diagram of a capacitor structure in accordance with some embodiments of the present disclosure.

FIG. 24 is a flow diagram of a method for manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of time, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure provides a semiconductor structure including image sensors and event sensors on a same wafer for a purpose of better detection of movement of an individual. The semiconductor structure can be applied in a photonic device, such as a camera, and provides advantages over a standard camera due to a high dynamic range. The event sensor may require a greater capacitance compared to an image sensor since more electrons are generated by an event sensor to be processed for a purpose of detection in changes of brightness. The semiconductor structure of the present disclosure further includes a capacitor structure formed in another wafer bonded to the wafer of BSI sensors. The capacitor structure formed in such other wafer can provide capacitance to the event sensors, while providing an advantage of simpler design layout and flexibility of capacitance adjustment compared to capacitors formed in an interconnect structure. Therefore, the present disclosure can provide improved forward capacity (FWC) and high dynamic range of a photonic device while avoiding a need to increase a size of the device.

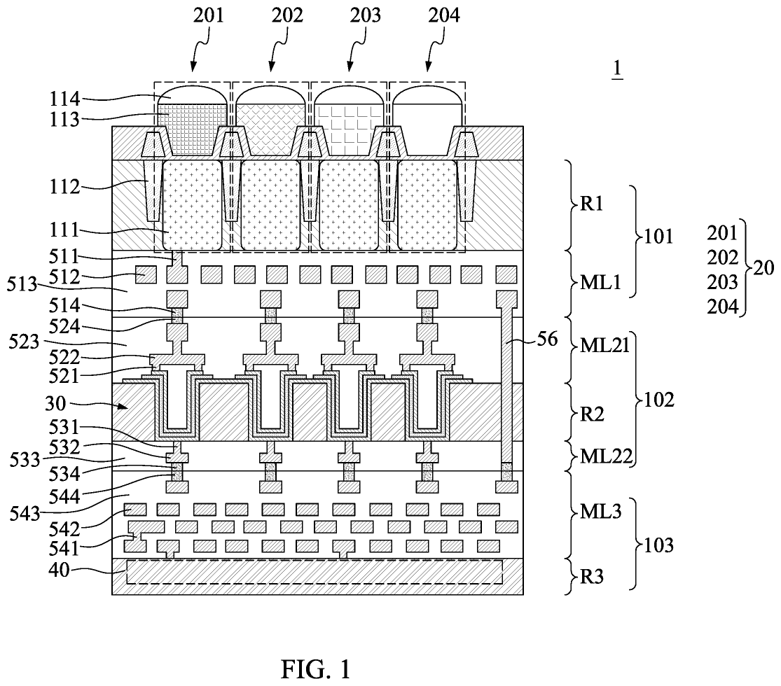

FIG. 1 is a schematic cross-sectional diagram of a semiconductor structure 1 in accordance with some embodiments of the present disclosure. The semiconductor structure 1 can be a photonic device including a capacitor structure 30 disposed in a wafer and bonded to another wafer having BSI sensors. The semiconductor structure 1 may be a wafer-on-wafer bonding structure. In some embodiments, the semiconductor structure 1 includes a first wafer 101, a second wafer 102 bonded to the first wafer 101, and a third wafer 103 bonded to the second wafer 102. In some embodiments, the second wafer 102 and the first wafer 101 are bonded face-to-face (in face-to-face bonding, a front side of the first wafer 101 is bonded to a front side of the second wafer 102). In some embodiments, the second wafer 102 and the third wafer 103 are bonded back-to-face (in back-to-face bonding, a backside of the second wafer 102 is bonded to a front side of the third wafer 103).

The first wafer 101 may include a substrate R1 and an interconnect structure ML1 disposed over a front side of the substrate R1. The substrate R1 can be a semiconductive layer, which may include a bulk semiconductor material, such as silicon, or other semiconductor materials, such as silicon germanium, silicon carbide, gallium arsenide, or the like. The substrate R1 may be of a first conductivity type, e.g., a P-type semiconductive substrate (acceptor type), or a second conductivity type, e.g., an N-type semiconductive substrate (donor type).

The interconnect structure ML1 includes a plurality of conductive features (including metal via features 511 and metal line features 512) surrounded by a plurality of inter-metal dielectric (IMD) layers 513. In some embodiments, the IMD layer 513 is directly over the substrate R1. In some embodiments, an insulating layer (not shown in the figures) is disposed over the substrate R1 covering transistors or photodiodes formed thereon, and the interconnect structure ML1 is formed over the insulating layer. In some embodiments, the insulating layer includes a dielectric material same as that of the IMD layers 513. In some embodiments, the conductive features include tungsten (W), aluminum (Al), copper (Cu), silver (Ag), gold (Au), titanium (Ti), tantalum (Ta), ruthenium (Ru), titanium-nitride (TiN), tantalum-nitride (TaN), ruthenium nitride (RuN), tungsten nitride (WN), or alloys thereof.

The conductive features include a plurality of metal line layers M0 to Mn, where n is a positive integer greater than 1, and a plurality of metal via layers, alternately arranged between the plurality of metal line layers M0 to Mn for electrical connection between the metal line layers. The metal line layer M0 may be the first metal line layer over the substrate R1, and the metal line layer Mn may be the topmost metal line layer of the interconnect structure ML1. Each of the metal line layers M0 to Mn includes a plurality of metal line features 512, and each of the metal via layers includes a plurality of metal via features 511. The metal line features 512 in the topmost metal line layer Mn can be used for hybrid bonding and electrical connection to another substrate, wafer, chip, die, or device (e.g., the first wafer 101 and the second wafer 102).

The semiconductor structure 1 may further include conductive features 514 formed over the interconnect structure ML1, and the conductive features 514 can be referred to as bonding features 514. The conductive features 514 may include a plurality of dummy metal line features or dummy metal segments electrically isolated from the metal line features 512 and the metal via features 511 for a purpose of hybrid bonding. In some embodiments, the conductive features 514 are at a surface of the interconnect structure ML1 opposite to the substrate R1. In some embodiments, the conductive features 514 are disposed in a bonding layer (not labeled) formed over the interconnect structure ML1, wherein the bonding layer includes a dielectric layer surrounding the conductive features 514. The dielectric layer of the bonding layer may include a dielectric material same as that of the IMD layers 513, and an interface between the dielectric layer of the bonding layer and the IMD layer 513 may be invisible. For a purpose of simplicity, the bonding layer is not labeled in the figures, and can be considered as a top layer of an interconnect structure ML21. It should be noted that the conductive features 514 are for hybrid bonding, and the conductive features 514 can be a small segment or block but not be in a “line” configuration. In addition, a quantity of the metal line layers can be adjusted according to application, and the disclosure is not limited to a number of metal line layers shown in the figures.

One or more backside image (BSI) sensors 20 is formed or disposed in the substrate R1 (e.g., on a backside of the substrate R1). The BSI sensors 20 are configured to receive an optical signal from the backside of the substrate R1. The BSI sensors 20 may include multiple BSI sensors (e.g., 201, 202, 203 and 204) for sensing optical signals with different ranges of wavelengths. In some embodiments, each of the BSI sensors 20 includes a sensing region 111, a color filter 113 and a micro-lens 114. In some embodiments, the sensing region 111 includes at least a transistor and one or more doping regions in the substrate R1. In some embodiments, the sensing region 111 include one or more photodiodes. In some embodiments, a plurality of isolations 112 are disposed between adjacent sensing regions 111 or between adjacent photodiodes. In some embodiments, the color filter 113 can be a red, green, or blue filter. FIG. 1 shows the BSI sensor 201 having a red filter, the BSI sensor 202 having a green filter, the BSI sensor 203 having a blue filter, and the BSI sensor 204 having a transparent filter (or no color filter) for a purpose of illustration. The semiconductor structure 1 can include more BSI sensors 20 according to a resolution of a photonic device (e.g., camera). In some embodiments, the BSI sensors 20 are formed on the backside of the substrate R1.

The second wafer 102 may include a substrate R2, the interconnect structure ML21 disposed over a front side of the substrate R2, and an interconnect structure ML22 disposed over a backside of the substrate R2. The substrate R2 can be similar to the substrate R1, and the interconnect structure ML21 can be similar to the interconnect structure ML1. The interconnect structure ML22 can be similar to the interconnect structure ML21 but with fewer metal line layers and fewer IMD layers. In some embodiments, the second wafer 102 is bonded to the first wafer 101 through the interconnect structures ML1 and ML21.

A capacitor structure 30 is formed and disposed in the substrate R2. The capacitor structure 30 may include multiple trench capacitors, wherein each of the trench capacitors extends from a front surface of the substrate R2 to a back surface of the substrate R2. In some embodiments, the capacitor structure 30 penetrates the substrate R2. Each of the trench capacitors may have an upper electrode and a lower electrode. The upper electrode of the trench capacitor electrically connects to one of the BSI sensors 20 in the first wafer 101 through the interconnect structures ML1 and ML21. The lower electrode of the trench capacitor electrically connects to the third wafer R3 through the interconnect structure ML22. In some embodiments, the capacitor structure 30 is overlapped by at least one of the BSI sensors 20.

Similar to the interconnect structure ML1, the interconnect structure ML21 includes a plurality of conductive features (including metal via features 521 and metal line features 522) surrounded by a plurality of IMD layers 523. In some embodiments, the IMD layer 523 is directly over the substrate R2. In some embodiments, an insulating layer (not shown in the figures) is disposed over the substrate R1 covering the capacitor structure 30 formed thereon, and the interconnect structure ML21 is formed over the insulating layer. In some embodiments, the insulating layer includes a dielectric material same as that of the IMD layers 523. Materials of the conductive features of the interconnect structure ML21 can be similar to the materials of the conductive features of the interconnect structure ML1 described above, and repeated description is omitted herein.

The conductive features of the interconnect structure ML21 include a plurality of metal line layers M0 to Mn, where n is a positive integer greater than 1, and a plurality of metal via layers, alternately arranged between the plurality of metal line layers M0 to Mn for electrical connection between the metal line layers. The metal line layer M0 may be the first metal line layer over the substrate R2, and the metal line layer Mn may be the topmost metal line layer of the interconnect structure ML21. Each of the metal line layers M0 to Mn includes a plurality of metal line features 522, and each of the metal via layers includes a plurality of metal via features 521. The semiconductor structure 1 may further include conductive features 524 formed over the interconnect structure ML21, wherein the conductive features 524 can be referred to as bonding features 524. In some embodiments, the conductive features 524 are at a surface of the interconnect structure ML21 opposite to the substrate R2. It should be noted that a quantity of the metal line layers can be adjusted according to application, and the disclosure is not limited to a quantity of metal line layers shown in the figures.

The interconnect structure ML22 may include a plurality of metal line layers M0 to Mn, and a plurality of metal via layers, alternately arranged between the plurality of metal line layers M0 to Mn for electrical connection between the metal line layers. The metal line layer M0 may be the first metal line layer below the substrate R2, and the metal line layer Mn may be the bottom-most metal line layer of the interconnect structure ML22. Each of the metal line layers M0 to Mn includes a plurality of metal line features 532, and each of the metal via layers includes a plurality of metal via features 531. The metal line features 532 and the metal via features 531 are surrounded by a plurality of IMD layers 533. The semiconductor structure 1 may further include conductive features 534 formed below the interconnect structure ML22, wherein the conductive features 534 can be referred to as bonding features 534 for a purpose of hybrid bonding and electrical connection to another substrate (e.g., the third wafer 103). In some embodiments, a quantity of the metal line layers in the interconnect structure ML22 is equal to or less than 6.

The third wafer 103 may include a substrate R3 and an interconnect structure ML3 disposed over a front side of the substrate R3. The substrate R3 can be similar to the substrate R1 or R2, and the interconnect structure ML3 can be similar to the interconnect structure ML1 or ML21.

The interconnect structure ML3 may include a plurality of metal line layers M0 to Mn, and a plurality of metal via layers, alternately arranged between the plurality of metal line layers M0 to Mn for electrical connection between the metal line layers. The metal line layer M0 may be the first metal line layer over the substrate R3, and the metal line layer Mn may be the topmost metal line layer of the interconnect structure ML3. Each of the metal line layers M0 to Mn includes a plurality of metal line features 542, and each of the metal via layers includes a plurality of metal via features 541. The metal line features 542 and the metal via features 541 are surrounded by a plurality of IMD layers 543. The semiconductor structure 1 may further include conductive features 544 formed over the interconnect structure ML3, wherein the conductive features 544 can be referred to as bonding features 544 for a purpose of hybrid bonding and electrical connection to another substrate (e.g., the second wafer 102).

A logic device 40 is formed in the substrate R3 and configured to process an electrical signal from the BSI sensors 20. The electrical signals from the BSI sensors 20 may be transmitted to and stored in the capacitor structure 30 in the second wafer 102 through the interconnect structures ML1 and ML21. The electrical signals may be transmitted to the logic device 40 through the interconnect structures ML21 and ML3 for processing. The logic device 40 can be an array of transistors. The transistors of the logic device 40 can include one or more transistors, such as a planar transistor, a multi-gate transistor, a gate-all-around field-effect transistor (GAAFET), a fin field-effect transistor (FinFET), a vertical transistor, a nanosheet transistor, a nanowire transistor, a bipolar junction transistor (BJT), a high-electron-mobility transistor (HEMT or HEM FET), a selector (including Ovonic threshold switching or tunneling types), or a combination thereof.

The semiconductor structure 1 may further include a through via 56 penetrating the second wafer 102. The through via 56 is for a purpose of electrical connection between the first wafer 101 and the third wafer 103 without transmission through the second wafer 102. In some embodiments, electrical signals from the BSI sensors 20 are transmitted to the logic device 40 in the third wafer 103 through the through via 56. In some embodiments, the through via 56 electrically connects to one of the conductive features 544 in the interconnect structure ML3 (or the bonding layer) of the third wafer 103. In some embodiments, the through via 56 contacts the conductive feature 544 of the interconnect structure ML3 of the third wafer 103. In some embodiments, the through via 56 electrically connects to or contacts one of the conductive features 514 of the interconnect structure ML1 of the first wafer 101 (not shown in FIG. 1). In some embodiments, the through via 56 extends into the interconnect structure ML1. In some embodiments, the through via 56 electrically connects to or contacts one of the conductive features 512 of the interconnect structure ML1 of the first wafer 101 (not shown in FIG. 1).

In some embodiments, the conductive features 534 are formed in the bonding layer formed over the interconnect structure ML22, the through via 56 may be formed prior to the formation of the bonding layer, and the through via 56 stops on the conductive features 534. In such embodiments, the through via 56 contacts the conductive feature 534 and electrically connects to the conductive feature 544 through the conductive feature 534 (illustrated in other embodiments in following paragraphs).

It should be noted that the semiconductor structure 1 is for a purpose of illustration. An orientation of a substrate or a stacking order of the wafers 101, 102 and 103 can be different in accordance with different embodiments.

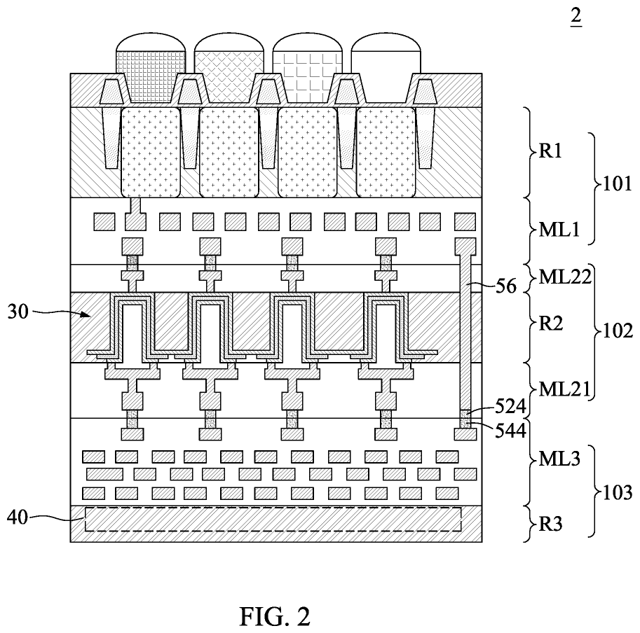

FIG. 2 is a schematic cross-sectional diagram of a semiconductor structure 2 in accordance with some embodiments of the present disclosure. The semiconductor structure 2 is similar to the semiconductor structure 1 except that a second wafer 102 is upside down compared to the second wafer 102 of the semiconductor structure 1. In some embodiments, the first wafer 101 and the second wafer 102 are bonded face-to-back (i.e., bonded using face-to-back bonding, wherein the front side of the first wafer 101 is bonded to the backside of the second wafer 102). In some embodiments, the second wafer 102 and the third wafer 103 are bonded face-to-face (i.e., bonded using face-to-face bonding, wherein the front side of the second wafer 102 is bonded to the front side of the third wafer 103).

In some embodiments, the second wafer 102 and the first wafer 101 are connected through the interconnect structures ML1 and ML22. In some embodiments, the second wafer 102 and the third wafer 103 are connected through the interconnect structures ML21 and ML3. In some embodiments, a lower electrode of a trench capacitor of the capacitor structure 30 in the substrate R2 is electrically connected to at least one of the BSI sensors 20 in the substrate R1 through the interconnect structures ML1 of the first wafer 101 and the interconnect structure ML22 of the second wafer 102. In some embodiments, an upper electrode of the trench capacitor of the capacitor structure 30 in the substrate R2 is electrically connected to the logic device 40 in the substrate R3 through the interconnect structures ML21 of the second wafer 102 and the interconnect structure ML3 of the third wafer 103.

As shown in FIG. 2, the through via 56 may be formed prior to the formation of the conductive feature 524 in the bonding layer. In some embodiments, the second wafer 102 is bonded to the first wafer 101, and then the through via 56 is formed to connect to the first wafer 101. In some embodiments, the bonding layer (including the conductive features 524) is formed after the formation of the through via 56, and the third wafer 103 is then bonded to the second wafer 102. Therefore, the through via 56 can electrically connect to the third wafer 103 through the conductive features 524 and 544.

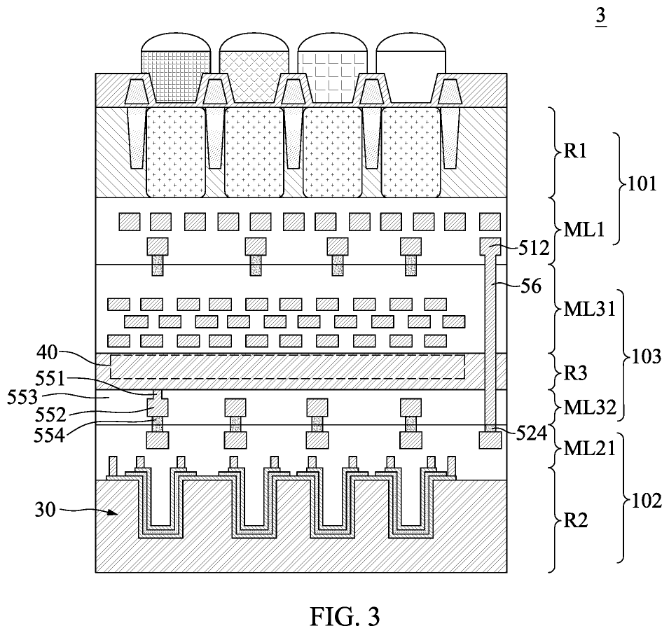

FIG. 3 is a schematic cross-sectional diagram of a semiconductor structure 3 in accordance with some embodiments of the present disclosure. The semiconductor structure 3 is similar to the semiconductor structure 1 except that a third wafer 103 is disposed between the first wafer 101 and the second wafer 102. In some embodiments, the first wafer 101 is bonded to the third wafer 103, and the third wafer 103 is bonded to the second wafer 102. The second wafer 102 of the semiconductor structure 3 may include the interconnect structure ML21, and the interconnect structure ML22 is absent. The third wafer 103 of the semiconductor structure 3 may include an interconnect structure ML31 disposed over a front side of a substrate R3, and an interconnect structure ML32 disposed over a backside of the substrate R3. The interconnect structure ML31 can be similar to the interconnect structure ML3 described above with reference to the semiconductor structures 1 and 2 shown in FIGS. 1 and 2. The interconnect structure ML32 can be similar to the interconnect structure ML22 described above with reference to the semiconductor structures 1 and 2 shown in FIGS. 1 and 2. The interconnect structure ML32 may also include metal line layers M0 to Mn, and a plurality of metal via layers alternately arranged between the plurality of metal line layers M0 to Mn. Each of the metal line layers M0 to Mn includes a plurality of metal line features 552, and each of the metal via layers includes a plurality of metal via features 551. The metal line features 552 and the metal via features 551 are surrounded by a plurality of IMD layers 553. The semiconductor structure 3 may further include conductive features 554 formed over the interconnect structure ML32, wherein the conductive features 554 can be referred to as bonding features 554 for a purpose of hybrid bonding and electrical connection to another substrate (e.g., the second wafer 102).

In some embodiments, the first wafer 101 and the third wafer 103 are bonded face-to-face (i.e., bonded using face-to-face bonding, wherein the front side of the first wafer 101 is bonded to the front side of the third wafer 103). In some embodiments, the interconnect structure ML1 and the interconnect structure ML31 are bonded, thereby bonding the first wafer 101 to the third wafer 103. In some embodiments, the third wafer 103 and the second wafer 102 are bonded back-to-face (i.e., bonded using back-to-face bonding, wherein the backside of the third wafer 103 is bonded to the front side of the second wafer 102). In some embodiments, the interconnect structure ML32 and the interconnect structure ML21 are bonded, thereby bonding the third wafer 103 to the second wafer 102. In some embodiments, one of electrodes of the capacitor structure 30 is electrically connected to the logic device 40 in the third wafer 103 through the interconnect structures ML21 and ML32, and another of the electrodes of the capacitor structure 30 is electrically connected to the BSI sensors 20 in the first wafer 101 through a through via 56.

The semiconductor structure 3 may further include the through via 56 penetrating the third wafer 103. The through via 56 of the semiconductor structure 3 can be similar to the through via 56 of the semiconductor structure 1 or 2 except that the through via 56 of the semiconductor structure 3 electrically connects the first wafer 101 to the second wafer 102. The through via 56 is for a purpose of electrical connection between the first wafer 101 and the second wafer 102 without transmission through the third wafer 103. In some embodiments, electrical signals from the BSI sensors 20 are transmitted to the capacitor structure 30 in the second wafer 102 through the through via 56. In some embodiments, the through via 56 electrically connects to the conductive feature 524 of the interconnect structure ML21 (or of the bonding layer). In some embodiments, the through via 56 contacts the conductive feature 524 of the interconnect structure ML21 of the second wafer 102. In some embodiments, the through via 56 extends into the interconnect structure ML1. In some embodiments, the through via 56 electrically connects to or contacts a conductive feature 512 of the interconnect structure ML1 of the first wafer 101.

The BSI sensors 20 of the semiconductor structure 1, 2 or 3 may include at least an event sensor. The event sensor is a type of dynamic vision sensor, which is for perceiving movement of individual pixels as changes in luminance, and the event sensor can output only data which has changed with low latency. For a purpose of illustration, the BSI sensors 20 configured for capturing color images are referred to as image sensors, and the BSI sensors 20 configured for detecting changes in brightness are referred to as event sensors. The event sensor can be applied with a red, green or blue filter for a specific range of wavelengths of detection. In some embodiments, no filter (or a transparent filter) is applied to the event sensor, and such event sensor can detect optical signals of all wavelengths.

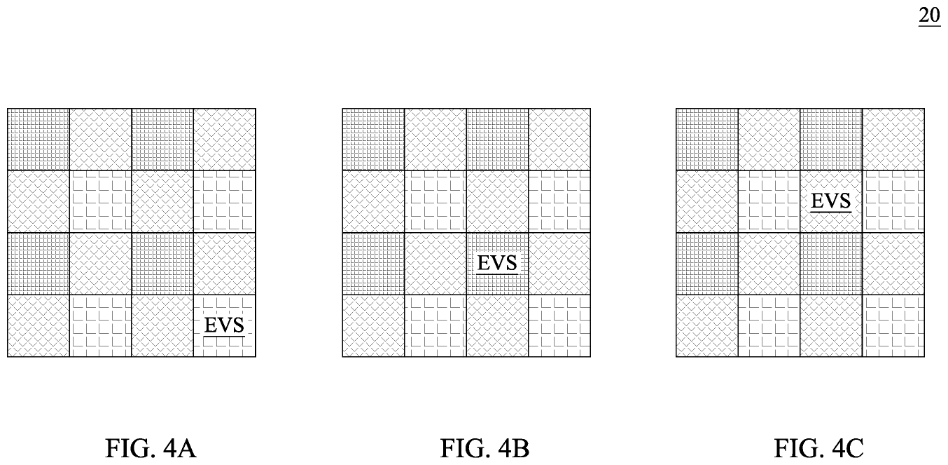

As shown in FIGS. 4A, 4B and 4C, the BSI sensors 20 shown in FIGS. 1, 2 and 3 can include multiple BSI sensors with different colors, and FIGS. 4A, 4B and 4C are diagrams in accordance with different embodiments of the present disclosure showing the event sensor EVS applied in the BSI sensors with different colors. For instance, the event sensor EVS can be applied in a BSI sensor with a blue filter as shown in FIG. 4A; the event sensor EVS can be applied in a BSI sensor with a red filter as shown in FIG. 4B; and the event sensor EVS can be applied in a BSI sensor with a green filter as shown in FIG. 4C.

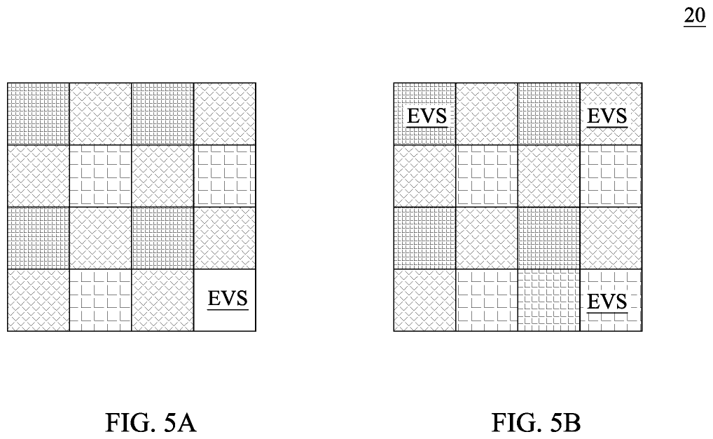

In other embodiments, the event sensor EVS can be designed to detect optical signals of all wavelengths, as shown in FIG. 5A. In some embodiments, the BSI sensors 20 can include multiple event sensors EVS as shown in FIG. 5B. However, a greater number of event sensors EVS may reduce a resolution of a device. In some embodiments, a ratio of the event sensors EVS to a total number of the BSI sensors 20 is substantially less than or equal to 1/10 for a purpose of high resolution.

The present disclosure provides a semiconductor structure including image sensors and event sensors on a same wafer for a purpose of better detection of movement of an individual. The semiconductor structure can be applied in a photonic device, such as a camera, and provides an advantage of a dynamic ranger greater than that of a standard camera. The event sensor may require a greater capacitance compared to an image sensor since more electrons are generated by the event sensor to be processed for a purpose of detection in changes of brightness. The semiconductor structure of the present disclosure includes a capacitor structure formed in a separate wafer bonded to the wafer of BSI sensors to provide capacitance to the BSI sensors, especially the event sensors. Therefore, the present disclosure can provide improved forward capacity (FWC) and higher dynamic range of a photonic device while eliminating need to increase a size of the device.

The capacitor structure 30 shown in FIG. 1, 2 or 3 may include multiple capacitors to electrically connect to different BSI sensors 20 according to optical signals they receive. In some embodiments, the capacitors and the event sensors have one-to-one relationship. In other words, one event sensor is electrically connected to one capacitor.

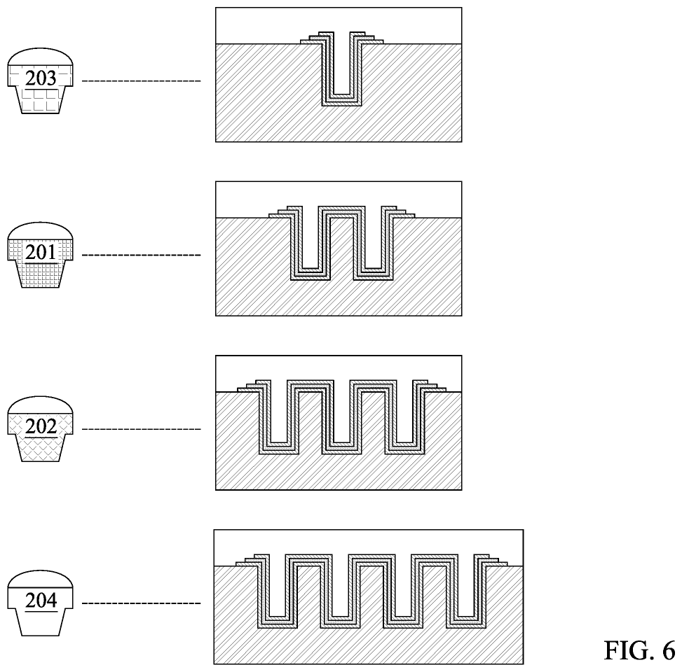

FIG. 6 is a diagram showing event sensors with different colors designed to connect to capacitors with different capacitances in accordance with some embodiments of the present disclosure. For a purpose of illustration, the capacitors are all trench capacitors, and all the trenches are substantially identical in all dimensions. In other words, a number of trench capacitors connected in series can represent a capacitance provided to an event sensor. A greater number of trench capacitors connected in series indicates a greater capacitance provided to the event sensor, and a capacitor with fewer trench capacitors connected in series indicates a smaller capacitance provided to the event sensor.

In some embodiments, when the BSI sensor 203 having a blue filter functions as an event sensor, the BSI sensor 203 is electrically connected to one trench capacitor. In some embodiments, when the BSI sensor 201 having a red filter functions as an event sensor, the BSI sensor 201 is electrically connected to two trench capacitors. In some embodiments, when the BSI sensor 202 having a green filter functions as an event sensor, the BSI sensor 202 is electrically connected to three trench capacitors. In some embodiments, when the BSI sensor 204 having a transparent filter functions as an event sensor, the BSI sensor 204 is electrically connected to four trench capacitors. It should be noted that FIG. 6 is for a purpose of illustrating an approach of assigning capacitances of event sensors with different colors, but is not intended to limit a certain color of an event sensor to a certain number of trench capacitors.

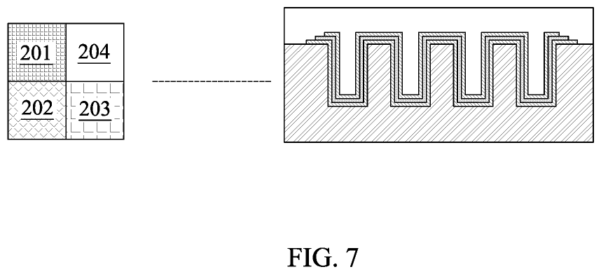

FIG. 7 is a diagram showing an event sensor applied in a pixel, wherein the pixel is electrically connected to one or more trench capacitors in series in accordance with some embodiments of the present disclosure. The BSI sensors 20 shown in FIGS. 1, 2 and 3 may include multiple pixels, and a number of BSI sensors 20 in one pixel can be adjusted according to application. In some embodiments, the BSI sensors 20 together are referred to as a pixel structure 20. In some embodiments, a pixel includes four BSI sensors 20 as shown in FIG. 7. In some embodiments, the pixel includes the BSI sensor 201 having a red filter, the BSI sensor 202 having a green filter, the BSI sensor 203 having a blue filter, and the BSI sensor 204 having a transparent filter. In some embodiments, the pixel electrically connects to one or more trench capacitors in series. In other words, each pixel can have a determined capacitance of the trench capacitors of the pixel. It should be noted that any one of the BSI sensors 201, 202, 203 and 204 can be an event sensor. As illustrated above, an event sensor requires a greater capacitance than a normal image sensor, and thus, a capacitance of the capacitors connected to the pixel can be determined by a wavelength range of the event sensor.

However, the capacitor structure 30 of the present disclosure is not limited to connection to the event sensor. The image sensors can electrically connect to one or more capacitors of the capacitor structure for better image processing efficiency. In some embodiments, the capacitors connected to an image sensor are electrically isolated from the capacitors connected to an event sensor (as shown in FIG. 6). In some embodiments, the capacitors connected to an image sensor are electrically connected to the capacitors connected to an event sensor (as shown FIG. 7).

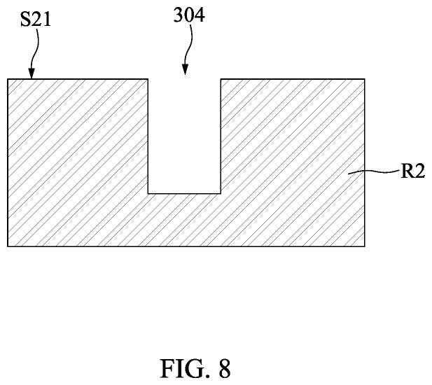

FIGS. 8 to 15 are schematic cross-sectional diagrams of a portion of the second wafer 102 showing various stages in formation of a trench capacitor in accordance with some embodiments of the present disclosure.

Referring to FIG. 8, a trench 304 is formed in the substrate R2. The trench 304 defines a position of a trench capacitor to be formed in the substrate R2. In some embodiments, an etching operation is performed on a top surface S21, which faces a front side of the substrate R2, to form the trench 304. In some embodiments, the etching operation is a time-mode etching operation. Dimensions (including depth, width and length) of the trench 304 can be adjusted according to application. In addition, a configuration of the trench 304 can be adjusted according to different etching operations, such as dry etching, wet etching, tilt etching, etc.

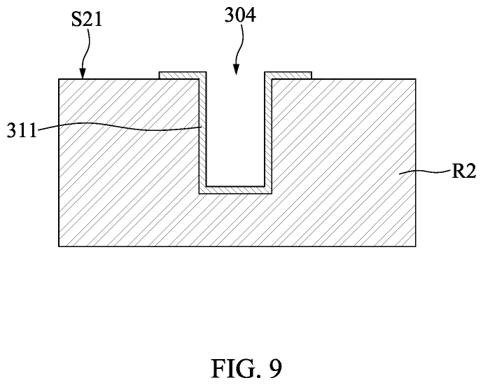

Referring to FIG. 9, a conductive layer 311 is formed over the top surface S21 of the substrate R2 in accordance with some embodiments of the present disclosure. The conductive layer 311 is conformal to a profile of the trench 304. In some embodiments, the conductive layer 311 covers the top surface S21 of the substrate R2, and an etching operation is then performed to form the conductive layer 311 as shown in FIG. 9. The conductive layer 311 can include a suitable conductive material, such as titanium (Ti), tantalum (Ta), erbium (Er), yttrium (Y), ytterbium (Yb), europium (Eu), terbium (Tb), lutetium (Lu), thorium (Th), scandium (Sc), hafnium (Hf), zirconium (Zr), alloys thereof, or a combination thereof. In some embodiments, the conductive layer 311 is formed by a sputtering operation or a deposition. In some embodiments, the deposition includes chemical vapor deposition (CVD), physical vapor deposition (PVD), atomic layer deposition (ALD), plasma-enhanced atomic layer deposition (PEALD), or a combination thereof.

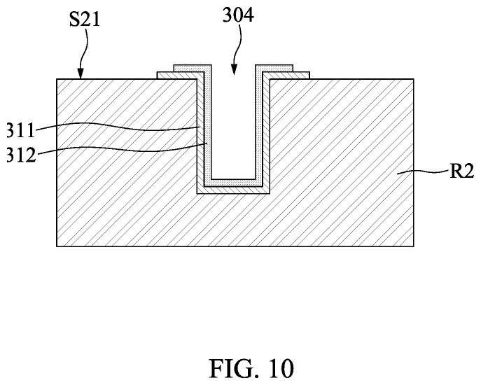

Referring to FIG. 10, a dielectric layer 312 is formed over and conformal to the conductive layer 311 in accordance with some embodiments of the present disclosure. The dielectric layer 312 is conformal to a profile of the trench 304. In some embodiments, the dielectric layer 312 is formed by a deposition, such as CVD, PVD, ALD or PEALD, followed by an etching operation. The dielectric layer 312 can include a suitable dielectric material, such as silicon oxide (SiOₓ), silicon nitride (SiₓN_{y}), silicon oxynitride (SiON), other low-k dielectric materials, high-k dielectric materials, or a combination thereof. In some embodiments, a portion of the conductive layer 311 above the top surface S21 is exposed through the dielectric layer 312 as shown in FIG. 10. In some embodiments, an entirety of the conductive layer 311 is covered by the dielectric layer 312 (not shown).

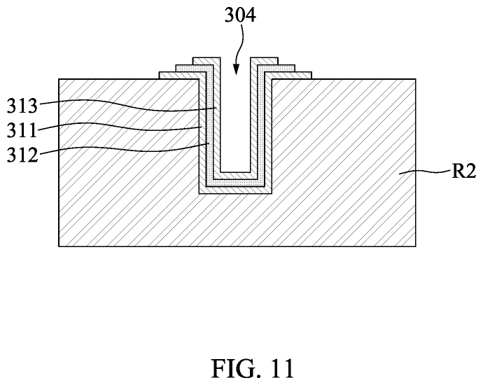

Referring to FIG. 11, a conductive layer 313 is formed over the dielectric layer 312 in accordance with some embodiments of the present disclosure. Formation of the conductive layer 313 can be similar to the formation of the conductive layer 311. Repeated description is omitted herein for a purpose of simplicity. The conductive layer 311, the dielectric layer 312, and the conductive layer 313 together define a trench capacitor. The dielectric layer 312 is an insulator of the trench capacitor, and a material and a thickness of the dielectric layer 312 can be adjusted according to a desired capacitance of the trench capacitor. The conductive layers 311 and 313 can be lower and upper electrodes of the trench capacitor, respectively. For a purpose of illustration, in the following description, the conductive layers 311 and 313 are respectively referred to as a lower electrode 311 and an upper electrode 313. In some embodiments, the conductive layers 311 and 313 are made of a same material.

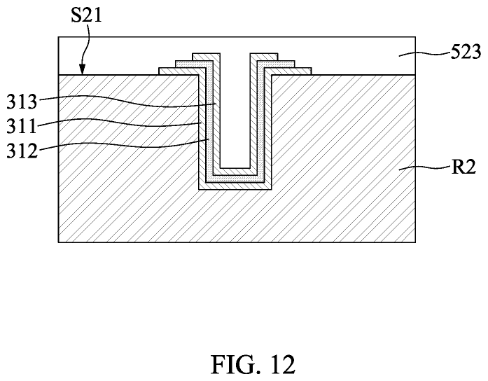

Referring to FIG. 12, an IMD layer 523 is formed over the trench capacitor and the substrate R2 in accordance with some embodiments of the present disclosure. In some embodiments, the IMD layer 523 contacts portions of the top surface S21 of the substrate R2. In some embodiments, the IMD layer 523 fills the trench 304 shown in FIG. 11. In some embodiments, the IMD layer 523 is the first IMD layer of the interconnect structure ML21. In some embodiments, the IMD layer 523 covers an entirety of the trench capacitor. In some embodiments, a planarization is performed on the IMD layer 523 after the formation of the IMD layer 523.

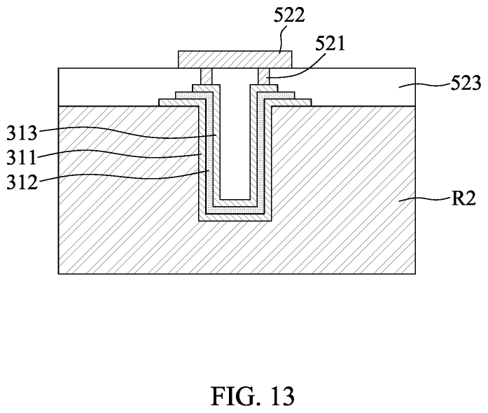

Referring to FIG. 13, one or more metal via features 521 and one or more metal line features 522 are formed over and electrically connected to the upper electrode 313 in accordance with some embodiments of the present disclosure. In some embodiments, an etching operation is performed on the IMD layer 523 to form openings over the upper electrode 313 for formation of the metal via features 521. In some embodiments, the metal via features 521 are formed in the openings and contact the upper electrode 313. In some embodiments, a deposition followed by an etching operation is performed to form the metal line feature 522 over the metal via features 521 to electrically connect to the upper electrode 313.

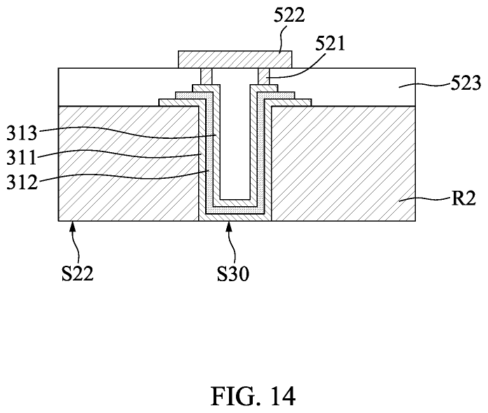

Referring to FIG. 14, a thickness of the substrate R2 is reduced from the backside of the substrate R2 in accordance with some embodiments of the present disclosure. In some embodiments, the substrate R2 is flipped over after the formation of the interconnect structure ML21 (it should be noted that only a portion of the interconnect structure ML21 is depicted in FIG. 14 for a purpose of brevity). In some embodiments, a lower portion of the substrate R2 below the lower electrode 311 is removed. The lower portion of the substrate R2 can be removed by, for example, a planarization, a chemical mechanical polishing (CMP), an etching operation, or a combination thereof. In some embodiments, a bottom surface S30 of the lower electrode 311 is exposed after the removal of the lower portion of the substrate R2. In some embodiments, after the removal of the lower portion, the substrate R2 has a bottom surface S22. In some embodiments, the bottom surface S22 of the substrate R2 is substantially aligned with the bottom surface S30 of the lower electrode 311.

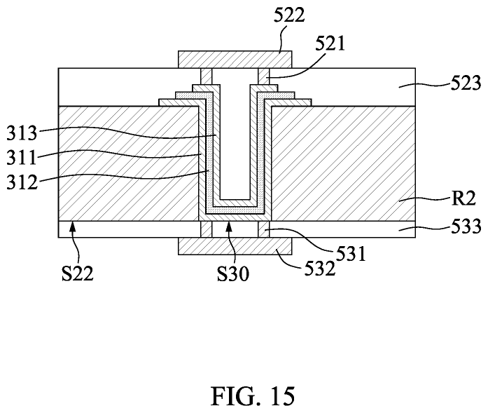

Referring to FIG. 15, operations similar to those depicted in FIGS. 12 and 13 are performed to form the IMD layer 533, the metal via features 531 and at least one metal line feature 532 in accordance with some embodiments of the present disclosure. In some embodiments, the IMD layer 533 contacts the bottom surface S22 of the substrate R2 and the bottom surface S30 of the lower electrode 311. In some embodiments, the IMD layer 533 is formed by a deposition, and a planarization is performed on the IMD layer 533 after the deposition. In some embodiments, one or more of the metal via features 531 are formed in the IMD layer 533. In some embodiments, the metal via features 531 contact the bottom surface S30 of the lower electrode 311. In some embodiments, a deposition followed by an etching operation is performed to form the metal line feature 532 over the metal via features 531 to electrically connect to the lower electrode 311. In some embodiments, the metal line feature 532 is disposed below the IMD layer 533, as shown in FIG. 15. In some embodiments, formation of other layers of the interconnect structure ML22 shown in FIG. 1 are subsequently performed on the intermediate structure of FIG. 15 to form the second wafer 102 as shown in FIG. 1.

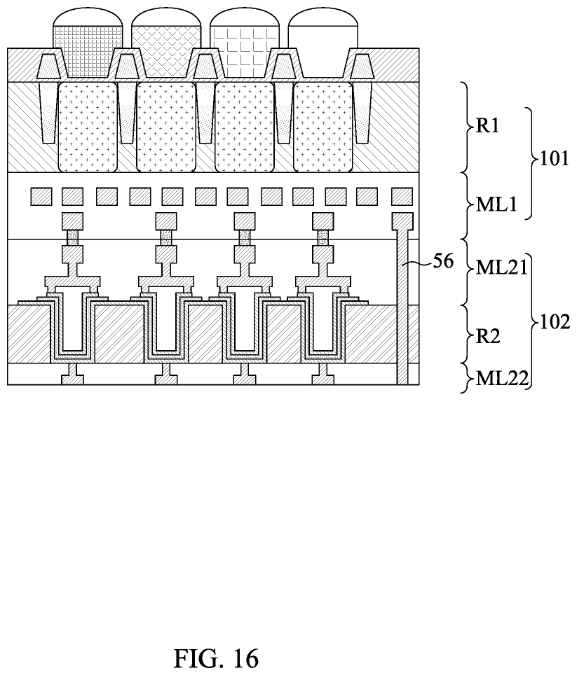

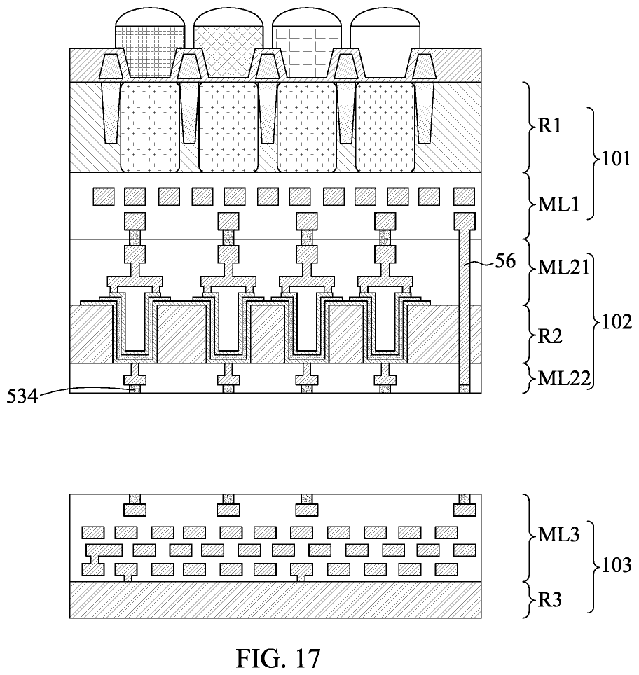

FIGS. 16 to 17 are schematic diagrams at different stages of formation of the semiconductor structure 1 as shown in FIG. 1 in accordance with some embodiments of the present disclosure.

Referring to FIG. 16, after the formation of the interconnect structure ML22, the second wafer 102 is bonded to the first wafer 101. In some embodiments, the through via 56 is formed after the bonding of the first wafer 101 to the second wafer 102. In some embodiments, an etching operation followed by a deposition is performed to form the through via 56. The through via 56 can include one or more suitable conductive materials, and it is not limited herein.

Referring to FIG. 17, a bonding layer including conductive features 534 is formed over the interconnect structure ML22 shown in FIG. 16. Different trench capacitors may electrically connect to different conductive features 534. In some embodiments, at least one conductive feature 534 is aligned with or contacts the through via 56. As described above, an interface is formed between the bonding layer and an IMD layer of the interconnect structure ML22, and for case of illustration, the bonding layer is shown as a bottom-most layer of the interconnect structure ML22. In some embodiments, the third wafer 103 is formed, and the first wafer 101 and the second wafer 102 are disposed over the third wafer 103. The first wafer 101 and the second wafer 102 may then be moved toward the third wafer 103, and a hybrid bonding operation can be performed to bond the second wafer 102 to the third wafer 103. The semiconductor structure 1 shown in FIG. 1 is thereby formed.

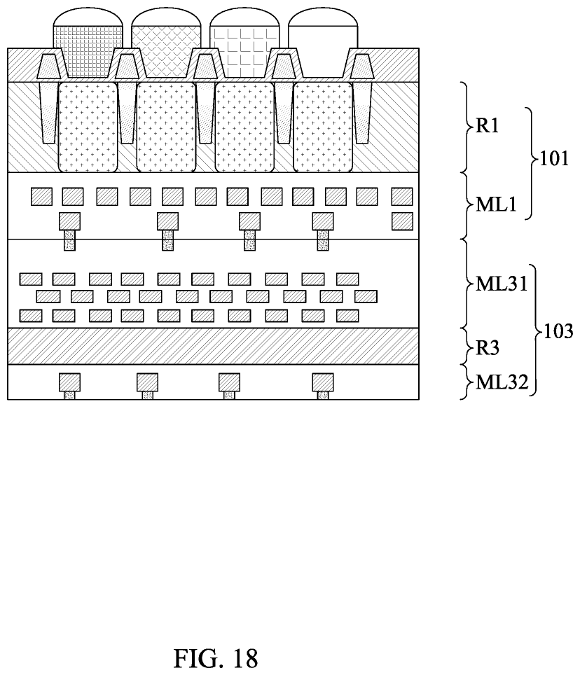

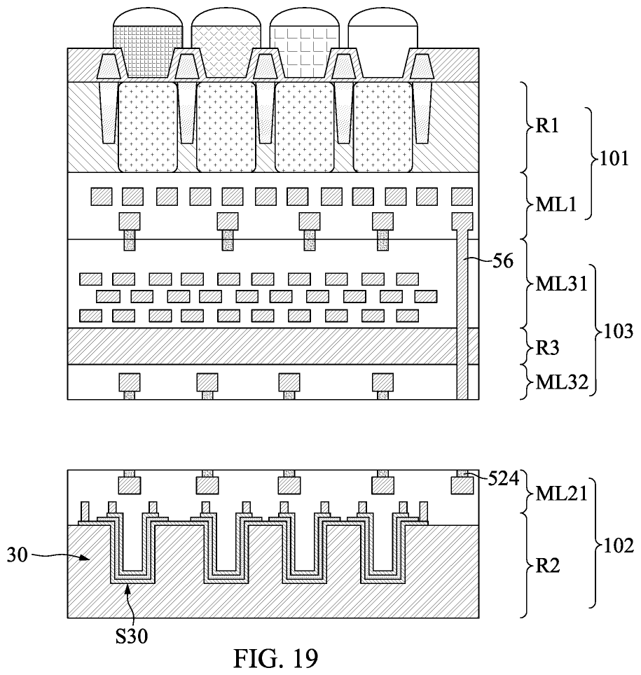

FIGS. 18 to 19 are schematic diagrams at different stages of formation of the semiconductor structure 3 as shown in FIG. 3 in accordance with some embodiments of the present disclosure.

Referring to FIGS. 18 to 19, in accordance with some embodiments of the present disclosure, the third wafer 103 is bonded to the first wafer 101. In some embodiments, as shown in FIG. 19, a through via 56 is formed after the third wafer 103 and the first wafer 101 are bonded. In some embodiments, the third wafer 103 and the first wafer 101 are disposed over the second wafer 102. It should be noted that, in this embodiment, the second wafer 102 does not include the interconnect structure ML22, and the bottom surface S30 of the trench capacitor is embedded in and covered by the substrate R2. The third wafer 103 is then bonded to the second wafer 102, and the semiconductor structure 3 is thereby formed. In some embodiments, an end of the through via 56 is exposed prior to the bonding of the third wafer 103 to the second wafer 102.

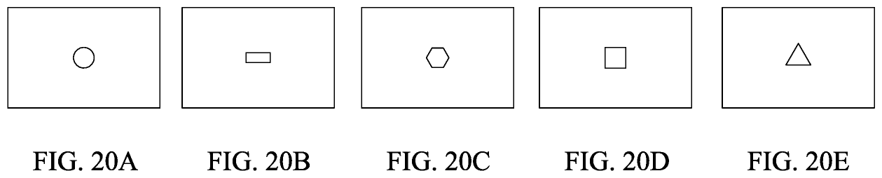

FIGS. 20A to 20E are schematic diagrams of top views of trench capacitors in accordance with different embodiments of the present disclosure. A configuration of the trench 304 shown in FIG. 8 from a top view perspective can be adjusted according to application. For instance, the trench 304 can be circular as shown in FIG. 20A, rectangular as shown in FIG. 20B, hexagonal as shown in FIG. 20C, square as shown in FIG. 20D, or triangular as shown in FIG. 20E. The configurations shown in FIGS. 20A to 20E are for a purpose of illustration, but are not intended to limit the present disclosure.

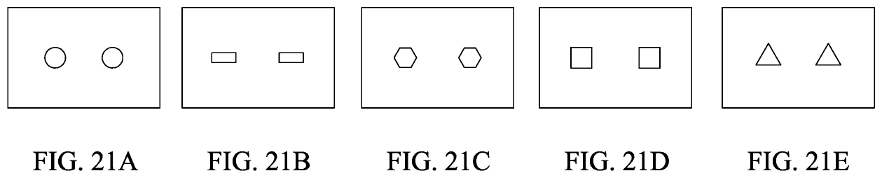

FIGS. 21A to 21E are schematic diagrams of top views of trench capacitors in accordance with different embodiments of the present disclosure showing trench capacitors in a same wafer having similar or identical configurations. For instance, pairs of adjacent trenches can be circular as shown in FIG. 21A, rectangular as shown in FIG. 21B, hexagonal as shown in FIG. 21C, square as shown in FIG. 21D, or triangular as shown in FIG. 21E. The configurations shown in FIGS. 21A to 21E are for a purpose of illustration, but are not intended to limit the present disclosure.

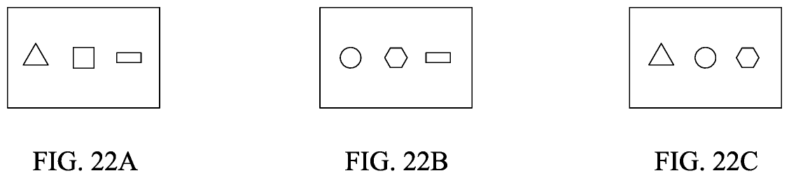

FIGS. 22A to 22C are schematic diagrams of top views of trench capacitors in accordance with different embodiments of the present disclosure showing trench capacitors in a same wafer having different configurations. Configurations of the trenches 304 formed on the same substrate R2 in the operation depicted in FIG. 8 from a top view perspective can be adjusted according to application. In some embodiments, as shown in FIG. 22A, the trenches 304 formed in the substrate R2 may have configurations of a triangle, a square, and a rectangle from the top view. In some embodiments, as shown in FIG. 22B, the trenches 304 formed in the substrate R2 may have configurations of a circle, a hexagon, and a rectangle from the top view. In some embodiments, as shown in FIG. 22C, the trenches 304 formed in the substrate R2 may have configurations of a triangle, a circle, and a hexagon from the top view. FIGS. 22A, 22B and 22C are exemplary embodiments to show different combinations, but they are not intended to limit the present disclosure.

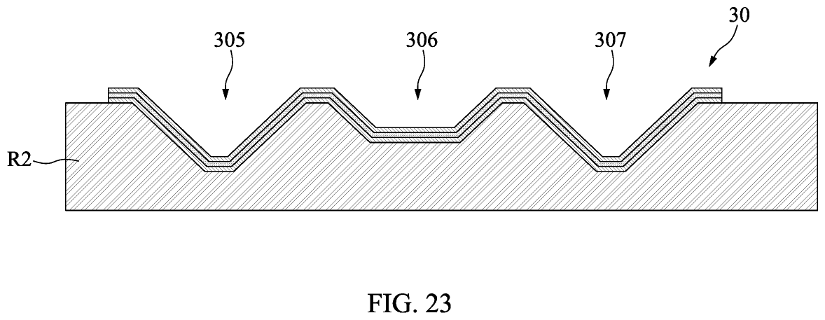

FIG. 23 is a schematic cross-sectional diagram of a capacitor structure 30 in accordance with some embodiments of the present disclosure. A configuration of the capacitor structure 30 from a cross-sectional view can be adjusted according to application. For example, the capacitor structure 30 shown in FIG. 23 is formed as a trench 305, a trench 306 and a trench 307. In some embodiments, each of the trenches 305, 306 and 307 has a wider top and a narrower bottom. Depths of the trenches 305, 306 and 307 can be different. In some embodiments, a depth of the trench 306 is less than those of the trenches 305 and 307. FIG. 23 is an exemplary embodiment, but is not intended to limit the present disclosure.

To conclude the processes of the embodiments as described above, a method 700 is provided.

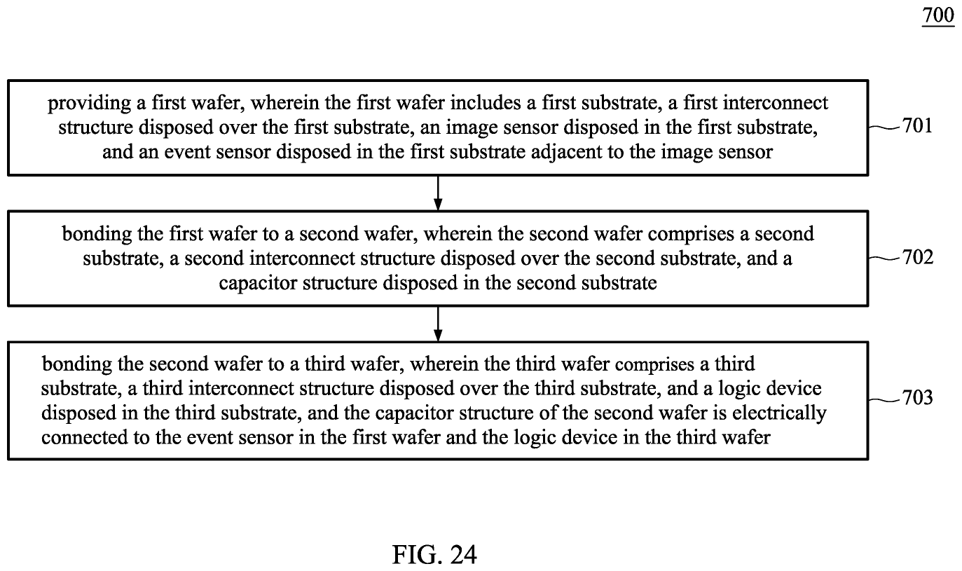

FIG. 24 is a flow diagram of the method 700 for manufacturing a semiconductor structure in accordance with some embodiments of the present disclosure. The method 700 includes a number of operations (701, 702 and 703), and the description and illustration are not deemed as a limitation to the sequence of the operations. In the operation 701, a first wafer is provided, wherein the first wafer includes a first substrate, a first interconnect structure disposed over the first substrate, an image sensor disposed in the first substrate, and an event sensor disposed in the first substrate adjacent to the image sensor. In the operation 702, the first wafer is bonded to a second wafer, wherein the second wafer comprises a second substrate, a second interconnect structure disposed over the second substrate, and a capacitor structure disposed in the second substrate. In the operation 703, the second wafer is bonded to a third wafer, wherein the third wafer comprises a third substrate, a third interconnect structure disposed over the third substrate, and a logic device disposed in the third substrate, and the capacitor structure of the second wafer is electrically connected to the event sensor in the first wafer and the logic device in the third wafer.

The operations of the method 700 can be rearranged or otherwise modified within the scope of the various aspects. In some embodiments, additional processes are provided before, during, and after the method 700, and some other processes are only briefly described herein. Thus, other implementations are possible within the scope of the various aspects described herein.

In accordance with some embodiments of the disclosure, a semiconductor structure is provided. The semiconductor structure includes an image sensor, disposed in a first substrate, wherein the first substrate includes a front side and a backside, and the image sensor is configured to receive an optical signal from the backside of the substrate; an event sensor, disposed in the first substrate adjacent to the image sensor; a capacitor structure, disposed in a second substrate, wherein the second substrate is disposed at the front side of the first substrate, and wherein a first electrode of the capacitor structure is electrically connected to the event sensor; and a logic device, disposed in a third substrate, wherein the third substrate is disposed at a front side of the second substrate, and wherein a second electrode of the capacitor structure is electrically connected to the logic device.

In accordance with some embodiments of the disclosure, a semiconductor structure is provided. The semiconductor structure includes a first wafer, including a first substrate and a first interconnect structure; a pixel structure, disposed in the first wafer and comprising a first image sensor, disposed at a backside of the first substrate and configured to receive an optical signal from the backside of the first substrate, and a first event sensor, disposed at the backside of the first substrate and adjacent to the image sensor; a second wafer, including a second substrate and a second interconnect structure; a plurality of capacitors, disposed in the second substrate, wherein a first capacitor of the plurality of capacitors is configured to receive electrons from the image sensor generated by the optical signal, and a second capacitor of the plurality of capacitors is configured to receive electrons from the first event sensor generated by the optical signal; a third wafer, including a third substrate and a third interconnect structure; and a logic device, disposed in third substrate and configured to process electrical signals from the first capacitor and the second capacitor.

In accordance with some embodiments of the disclosure, a method for manufacturing a semiconductor structure is provided. A first wafer is provided, wherein the first wafer includes a first substrate, a first interconnect structure disposed over the first substrate, an image sensor disposed in the first substrate, and an event sensor disposed in the first substrate adjacent to the image sensor. The first wafer is bonded to a second wafer, wherein the second wafer comprises a second substrate, a second interconnect structure disposed over the second substrate, and a capacitor structure disposed in the second substrate. The second wafer is bonded to a third wafer, wherein the third wafer comprises a third substrate, a third interconnect structure disposed over the third substrate, and a logic device, disposed in the third substrate, and wherein the capacitor structure of the second wafer is electrically connected to the event sensor in the first wafer and the logic device in the third wafer.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
an image sensor, disposed in a first substrate, wherein the first substrate includes a front side and a backside, and the image sensor is configured to receive an optical signal from the back side of the first substrate;
an event sensor, disposed in the first substrate adjacent to the image sensor;
a capacitor structure, disposed in a second substrate, wherein the second substrate is disposed at the front side of the first substrate, and wherein a first electrode of the capacitor structure is electrically connected to the event sensor; and
a logic device, disposed in a third substrate, wherein the third substrate is disposed at the front of the first substrate, and wherein a second electrode of the capacitor structure is electrically connected to the logic device.

2. The semiconductor structure of claim 1, further comprising:
a first interconnect structure, disposed at the front side of the first substrate; and
a second interconnect structure, disposed at a first side of the second substrate, wherein the first interconnect structure is bonded to the second interconnect structure.

3. The semiconductor structure of claim 2, further comprising:
a third interconnect structure, disposed at a second side opposite to the first side of the second substrate;
a fourth interconnect structure, disposed at a front side of the third substrate, wherein the third interconnect structure is bonded to the fourth interconnect structure.

4. The semiconductor structure of claim 2, wherein the first side of the second substrate is a front side of the second substrate.

5. The semiconductor structure of claim 2, wherein the first side of the second substrate is a backside of the second substrate.

6. The semiconductor structure of claim 1, further comprising:
a through via, penetrating the second substrate and electrically connecting the first substrate to the third substrate.

7. The semiconductor structure of claim 1, further comprising:
a through via, penetrating the third substrate and electrically connecting the first substrate to the second substrate.

8. A semiconductor structure, comprising:
a first wafer, including a first substrate and a first interconnect structure;
a pixel structure, disposed in the first wafer, and comprising:
a first image sensor, disposed at a backside of the first substrate and configured to receive an optical signal from the backside of the first substrate; and
a first event sensor, disposed at the backside of the first substrate and adjacent to the image sensor;
a second wafer, including a second substrate and a second interconnect structure;
a plurality of capacitors, disposed in the second substrate, wherein a first capacitor of the plurality of capacitors is configured to receive electrons from the first image sensor generated by the optical signal, and a second capacitor of the plurality of capacitors is configured to receive electrons from the first event sensor generated by the optical signal;
a third wafer, including a third substrate and a third interconnect structure; and
a logic device, disposed in third substrate and configured to process electrical signals from the first capacitor and the second capacitor.

9. The semiconductor structure of claim 8, wherein the plurality of capacitors vertically overlaps the logic device.

10. The semiconductor structure of claim 8, wherein the plurality of capacitors vertically overlaps the pixel structure.

11. The semiconductor structure of claim 8, wherein the second wafer further includes a fourth interconnect structure, disposed between the second substrate and the third wafer, and the logic device is electrically connected to the plurality of capacitors through the third interconnect structure and the fourth interconnect structure.

12. The semiconductor structure of claim 8, further comprising:
a through via, penetrating the second wafer, wherein the through via extends from the first interconnect structure and stops in the third interconnect structure to electrically connect the first wafer to the third wafer.

13. The semiconductor structure of claim 8, wherein the third wafer is disposed between the second wafer and the first wafer, and the first capacitor and the second capacitor are electrically connected to the image sensor and the event sensor through a through via penetrating the third wafer.

14. The semiconductor structure of claim 8, wherein the pixel structure further includes a second image sensor and a third image sensor, the plurality of capacitors further includes a third capacitor and a fourth capacitor, the second image sensor is electrically connected to the third capacitor, and the third image sensor is electrically connected to the fourth capacitor.

15. The semiconductor structure of claim 14, wherein the first capacitor, the second capacitor, the third capacitor and the fourth capacitor are connected in series.

16. The semiconductor structure of claim 14, wherein the first capacitor, the second capacitor, the third capacitor and the fourth capacitor are electrically isolated.

17. The semiconductor structure of claim 16, wherein the first capacitor, the second capacitor, the third capacitor and the fourth capacitor have different capacitances.

18. A method for manufacturing a semiconductor structure, comprising:
providing a first wafer, wherein the first wafer includes a first substrate, a first interconnect structure disposed over the first substrate, an image sensor disposed in the first substrate, and an event sensor disposed in the first substrate adjacent to the image sensor;
bonding the first wafer to a second wafer, wherein the second wafer comprises a second substrate, a second interconnect structure disposed over the second substrate, and a capacitor structure disposed in the second substrate; and
bonding the second wafer to a third wafer, wherein the third wafer comprises a third substrate, a third interconnect structure disposed over the third substrate, and a logic device, disposed in the third substrate, and wherein the capacitor structure of the second wafer is electrically connected to the event sensor in the first wafer and the logic device in the third wafer.

19. The method of claim 18, wherein the first interconnect structure of the first wafer and the second interconnect structure of the second wafer are bonded, thereby electrically connecting the capacitor structure to the event sensor.

20. The method of claim 18, wherein the second wafer further includes a fourth interconnect structure disposed on a side of the second substrate opposite to the second interconnect structure, and wherein the fourth interconnect structure of the second wafer and the third interconnect structure of the third wafer are bonded, thereby electrically connecting the capacitor structure to the logic device.
